(19) United States
(12) Patent Application Publication
(10) Pub. No.: US 2026/0139409 A1
(43) Pub. Date: May 21, 2026

(54) Beta-Cesium Cadmium Silicon Sulfide Compound, Beta-Cs2CdSi4S10 Nonlinear Optical Crystal and Preparation Methods and Applications Thereof

(71) Applicant: XinJiang Technical Institute of Physics & Chemistry, Chinese Academy of Sciences, Urumqi (CN)

(72) Inventors: Shilie PAN, Urumqi (CN); Yabo WU, Urumqi (CN); Chen CUI, Urumqi (CN); Xinchen CHEN, Urumqi (CN)

(21) Appl. No.: 19/309,391

(22) Filed: Aug. 25, 2025

(30) Foreign Application Priority Data
Nov. 15, 2024 (CN) 2024116320450

(51) Int. Cl. C30B 29/46; C01B 33/00; C30B 11/00; G02F 1/355

(52) U.S. Cl. CPC C30B 29/46; C01B 33/00; C30B 11/003; G02F 1/3551; C01P 2002/74; C01P 2006/60; G02F 2203/11

(57) ABSTRACT

The present invention provides a β-cesium cadmium silicon sulfide compound, a β-Cs₂CdSi₄S₁₀ infrared nonlinear optical crystal, as well as their preparation methods and applications. The β-cesium cadmium silicon sulfide compound has a chemical formula β-Cs₂CdSi₄S₁₀ and a molecular weight of 755.04. The β-Cs₂CdSi₄S₁₀ infrared nonlinear optical crystal belongs to the tetragonal crystal system, its space group is I-4, and its unit cell parameters are: a=8.4233(7) Å, c=14.6136(12) Å, and the unit cell volume is 1036.86(19) Å³. The present invention adopts a vacuum packaging method to prepare a β-Cs₂CdSi₄S₁₀ infrared nonlinear optical crystal. By using the kurtz-berry method, it was found that the frequency doubling effect of β-Cs₂CdSi₄S₁₀ crystal is approximately 1.1-1.2 times that of AgGaS₂(AGS). By using the UV-visible diffuse reflection, it was found that the β-Cs₂CdSi₄S₁₀ crystal has the crystal bandgap of 4.21 eV, the UV cutoff edge of 254 nm, and the infrared transparency range greater than 13 μm. The preparation method of the β-Cs₂CdSi₄S₁₀ infrared nonlinear optical crystal of the present invention is simple, with a short growth period, and avoids the leakage and contamination of raw materials. The β-Cs₂CdSi₄S₁₀ infrared nonlinear optical crystal of the present invention can be used to fabricate conversion devices for high-power laser output applications and has important applications in atmospheric remote sensing and communication fields.

### TECHNICAL FIELD OF THE INVENTION

The present invention belongs to the field of a β-cesium cadmium silicon sulfide compound, a β-Cs2CdSi4S10 infrared nonlinear optical crystal, as well as their preparation methods and applications.

### BACKGROUND OF THE INVENTION

Mid-infrared and far-infrared lasers are particularly important in aerospace technology, chemical detection, and environmental monitoring. The main method for approaching mid-infrared and far-infrared lasers is conversion in nonlinear frequency, which converts existing near-infrared lasers into mid-infrared and far-infrared wavelengths. Its core component is a nonlinear optical crystal. As is well known, the nonlinear optical crystals currently used in the mid-infrared to far-infrared bands are Chinese commercially available crystals such as AgGaS2 (AGS), AgGaSe2 (AGSe), and ZnGeP2 (ZGP). However, these semiconductor crystals have shortcomings such as small bandgap and low damage threshold, which to some extent limit their application in high-power lasers. Due to the fact that the infrared nonlinear optical materials with wide bandgap can avoid two-photon absorption and residual absorption problems at 1-2 μm, and have a large laser-induced damage threshold, the device is more suitable for high-power laser applications. Therefore, the preparation of novel infrared nonlinear optical crystal materials with wide bandgap is of great significance and practical value.

In summary, when designing and developing mid-infrared to far-infrared nonlinear optical crystals for high-power and high-energy laser devices, it is urgent to obtain crystals with wide bandgap, large nonlinear coefficient, wide transmission range, and moderate birefringence.

### SUMMARY OF THE INVENTION

An object of the present invention is to provide a novel compound capable of producing infrared nonlinear optical crystals with wide bandgap, large nonlinear coefficient, wide transmission range, and moderate birefringence.

Another object of the present invention is to provide a method for preparing the above-mentioned novel compound.

A further object of the present invention is to provide an infrared nonlinear optical crystal with wide bandgap, large nonlinear coefficient, wide transmission range, and moderate birefringence.

Another object of the present invention is to provide a method for preparing the above-mentioned infrared nonlinear optical crystal.

Another object of the present invention is to provide the use of the above-mentioned infrared nonlinear optical crystal.

The present invention provides a β-cesium cadmium silicon sulfide compound, with a chemical formula β-Cs2CdSi4S10 and a molecular weight of 755.04.

The present invention provides a method for preparing a β-Cs2CdSi4S10 compound, which adopts a vacuum packaging method.

In an embodiment, the method for preparing a β-Cs2CdSi4S10 compound adopting the vacuum packaging method comprises the following steps:

Mixing evenly a Cs-containing compound, a Cd-containing compound, a Si-containing compound, and a S-containing compound in a molar ratio of Cs:Cd:Si:S of 2:1:4:10 and placing them in a quartz tube with a diameter of 45 mm; evacuating the quartz tube to a vacuum degree of 1×10−3 Pa; sealing the quartz tube with a flame and placing it in a muffle furnace; heating the muffle furnace at a rate of 5-10° C./h to 630-670° C. and maintaining the temperature for 24 hours, then slowly cooling it to room temperature to obtain the β-cesium cadmium silicon sulfide compound β-Cs2CdSi4S10 of the present invention, wherein, the Cs-containing compound is CsI, the Cd-containing compound is CdS or Cd simple substance; the Si-containing compound is SiS2 or Si simple substance, and the S-containing compound is S simple substance.

The present invention provides a β-Cs2CdSi4S10 infrared nonlinear optical crystal, characterized in that the crystal belongs to the tetragonal crystal system, its space group is I-4, and its unit cell parameters are: a=8.4233(7) Å, c=14.6136(12) Å, and the unit cell volume is 1036.86(19) Å3.

The present invention provides a method for preparing a β-Cs2CdSi4S10 infrared nonlinear optical crystal, which adopts a Bridgeman-Stockbarge method or a vacuum packaging method.

In an embodiment, the method for preparing a β-Cs2CdSi4S10 infrared nonlinear optical crystal adopting a Bridgeman-Stockbarge method comprises the following steps:
a. Placing the β-Cs2CdSi4S10 compound prepared by a vacuum packaging method in a muffle furnace, heating the muffle furnace to 650° C. and maintaining the temperature for 100 hours to obtain a mixed melt;
b. Obtaining seed crystals of β-Cs2CdSi4S10 by slowly cooling the mixed melt obtained in step a at a rate of 3° C./h to 300° C. and then rapidly cooling it at a rate of 5-15° C./h to room temperature;
c. Placing the seed crystal prepared in step b at the bottom of a platinum crucible, and then placing the β-Cs2CdSi4S10 compound prepared in step a into the platinum crucible; sealing the platinum crucible and then placing it in a growth furnace; heating the growth furnace to 640-670° C. and maintaining the temperature for 100-200 hours; then lowering the platinum crucible at a rate of 1-10 mm/day while keeping the temperature of the growth furnace constant or cooling it at a rate of 2-3° C./h to 300° C.; quickly cooling it at a rate of 5-15° C./h to room temperature after finishing the growth; finally, opening the platinum crucible to obtain a β-Cs2CdSi4S10 infrared nonlinear optical crystal.

In an embodiment, the growth furnace used in the method for preparing a β-Cs2CdSi4S10 infrared nonlinear optical crystal of the present invention is a Bridgeman-Stockbarge furnace.

In an embodiment, the method for preparing a β-Cs2CdSi4S10 infrared nonlinear optical crystal adopting a vacuum packaging method comprises the following steps:

Placing the β-Cs2CdSi4S10 compound prepared by a vacuum packaging method in a quartz tube; evacuating the quartz tube to a vacuum degree of 1×10-3 Pa; sealing the quartz tube at high temperature and placing it in a muffle furnace; heating the muffle furnace to 630-650° C. and maintaining the temperature for 100 hours, then cooling it at a rate of 3° C./h to 300° C. and then rapidly cooling it at a rate of 5-10° C./h to room temperature; finally, opening the quartz tube to obtain aβ-Cs2CdSi4S10 infrared nonlinear optical crystal.

In an embodiment, in the method for preparing a β-Cs2CdSi4S10 infrared nonlinear optical crystal of the present invention, when using a quartz tube during the preparation, it is necessary to evacuate before sealing the quartz tube to avoid the volatilization of raw materials during the reaction, which may cause the quartz tube to explode.

The β-Cs2CdSi4S10 infrared nonlinear optical crystal of the present invention can be used in laser frequency conversion crystal devices for mid-infrared to far-infrared bands.

By using the method for preparing a β-Cs2CdSi4S10 infrared nonlinear optical crystal of the present invention, a β-Cs2CdSi4S10 infrared nonlinear optical crystal with a size of 1 mm×1 mm×0.5 mm can be obtained. By using large-sized quartz tubes and extending the growth period of the crystal, the β-Cs2CdSi4S10 infrared nonlinear optical crystal with a desired size can be obtained. During the growth period of the β-Cs2CdSi4S10 infrared nonlinear optical crystal, the crystal is prone to growth and transparent without encapsulation. The method of the present invention has the advantages of fast growth rate, low cost, and easy acquisition of large-sized crystals.

Because the Cs-containing compound, the Cd-containing compound, and the Si-containing compound used in the present invention can all use commercially available reagents and raw materials, the present invention has the advantages of simple operation, fast growth rate, and low cost. The crystal prepared by the method of the present invention can be used to fabricate crystal devices for frequency conversion, and has important applications in the fields of optics and communication.

In the structure of the β-Cs2CdSi4S10 infrared nonlinear optical crystal prepared by the present invention, the valences of Cs atom, Cd atom, Si atom, and S atom are +1, +2, +4, and −2, respectively. Si atom and Cd atom form tetrahedral structures of [SiS4] and [CdS4] with four adjacent S atoms, respectively. The four adjacent tetrahedra of [SiS4] form a super tetrahedron of [Si4S10] with a common vertex, which is connected to the tetrahedron of [CdS4] with a common vertex. All tetrahedra are arranged in a consistent orientation, forming a defect like diamond-like structure framework. The schematic diagram of the structure of the β-Cs2CdSi4S10 infrared nonlinear optical crystal of the present invention is shown in FIG. 3.

The β-Cs2CdSi4S10 infrared nonlinear optical crystal of the present invention has no special requirements for optical processing accuracy.

### BRIEF DESCRIPTION OF THE DRAWINGS

FIG. 1 shows the powder XRD spectrum of the β-Cs2CdSi4S10 compound prepared in Example 1 of the present invention;

FIG. 2 shows the UV-visible diffuse reflection of the β-Cs2CdSi4S10 infrared nonlinear optical crystal prepared in Example 7 of the present invention;

FIG. 3 is a schematic diagram of the structure of the β-Cs2CdSi4S10 infrared nonlinear optical crystal of the present invention;

FIG. 4 shows the working principle of the nonlinear optical device made of the β-Cs2CdSi4S10 infrared nonlinear optical crystal of the present invention, where: 1 is a laser, 2 is an emitting beam, 3 is a β-Cs2CdSi4S10 infrared nonlinear optical crystal, 4 is an output beam, and 5 is a filter.

### DETAILED DESCRIPTION OF THE INVENTION

The present invention will be further described in conjunction with the examples below. It should be noted that the following examples cannot be used as limitations on the protection scope of the present invention, and any improvements made on the basis of the present invention do not violate the spirit of the present invention. The raw materials or equipment used in the present invention are commercially available unless otherwise specified.

### Example 1. Preparation of β-Cs2CdSi4S10 Compound

According to the chemical reaction formula 2CsI+Cd+4Si+10S→Cs2CdSi4S10+I2↑, the β-Cs2CdSi4S10 compound is synthesized:

CsI powder, Cd powder, Si powder, and S powder were mixed evenly in a molar ratio of Cs:Cd:Si:S of 2:1:4:10, and were placed in a quartz tube with a diameter of 45 mm. The quartz tube was evacuated to a vacuum degree of 1×10−3 Pa, sealed with a flame and then placed in a muffle furnace. The muffle furnace was heated at a rate of 5° C./h to 670° C. for 24 hours, then slowly cooled to room temperature, the-cesium cadmium silicon sulfide (β-Cs2CdSi4S10) compound was obtained.

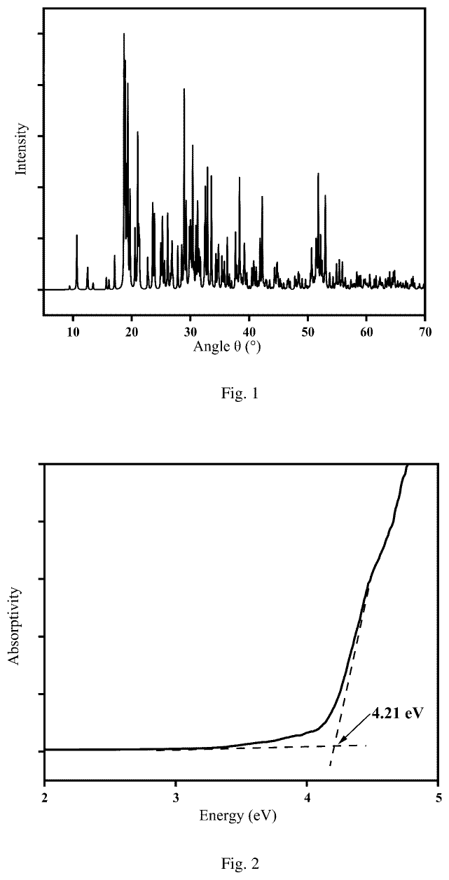

The powder XRD spectrum of the β-Cs2CdSi4S10 compound is shown in FIG. 1, and its UV-visible diffuse reflection is shown in FIG. 2.

After testing, the chemical formula of the compound is β-Cs2CdSi4S10, with a molecular weight of 755.04.

### Example 2. Preparation of β-Cs2CdSi4S10 Compound

According to the chemical reaction formula 2CsI+CdS+4SiS2+S→Cs2CdSi4S10+I2↑, the β-Cs2CdSi4S10 compound is synthesized:

CsI powder, CdS powder, SiS2 powder, and S powder were mixed evenly in a molar ratio of Cs:Cd:Si:S of 2:1:4:10, and were placed in a quartz tube with a diameter of 45 mm. The quartz tube was evacuated to a vacuum degree of 1×10−3 Pa, sealed with a flame and then placed in a muffle furnace. The muffle furnace was heated at a rate of 5° C./h to 630° C. for 24 hours, then slowly cooled to room temperature, the β-cesium cadmium silicon sulfide (β-Cs2CdSi4S10) compound was obtained.

### Example 3. Preparation of β-Cs2CdSi4S10 Compound

According to the chemical reaction formula 2CsI+Cd+4Si+10S→Cs2CdSi4S10+I2↑, the β-Cs2CdSi4S10 compound is synthesized:

CsI powder, Cd powder, Si powder, and S powder were mixed evenly in a molar ratio of Cs:Cd:Si:S of 2:1:4:10, and were placed in a quartz tube with a diameter of 45 mm. The quartz tube was evacuated to a vacuum degree of 1×10−3 Pa, sealed with a flame and then placed in a muffle furnace. The muffle furnace was heated at a rate of 7° C./h to 630° C. for 24 hours, then slowly cooled to room temperature, the β-cesium cadmium silicon sulfide (β-Cs2CdSi4S10) compound was obtained.

### Example 4. Preparation of β-Cs2CdSi4S10 Compound

According to the chemical reaction formula 2CsI+CdS+4SiS2+S→Cs2CdSi4S10+I2↑, the β-Cs2CdSi4S10 compound is synthesized:

CsI powder, CdS powder, SiS2 powder, and S powder were mixed evenly in a molar ratio of Cs:Cd:Si:S of 2:1:4:10, and were placed in a quartz tube with a diameter of 45 mm. The quartz tube was evacuated to a vacuum degree of 1×10−3 Pa, sealed with a flame and then placed in a muffle furnace. The muffle furnace was heated at a rate of 8° C./h to 630° C. for 24 hours, then slowly cooled to room temperature, the-cesium cadmium silicon sulfide (β-Cs2CdSi4S10) compound was obtained.

### Example 5. Preparation of β-Cs2CdSi4S10 Compound

According to the chemical reaction formula 2CsI+Cd+4Si+10S→Cs2CdSi4S10+I2↑, the β-Cs2CdSi4S10 compound is synthesized:

CsI powder, Cd powder, Si powder, and S powder were mixed evenly in a molar ratio of Cs:Cd:Si:S of 2:1:4:10, and were placed in a quartz tube with a diameter of 45 mm. The quartz tube was evacuated to a vacuum degree of 1×10−3 Pa, sealed with a flame and then placed in a muffle furnace. The muffle furnace was heated at a rate of 10° C./h to 630° C. for 24 hours, then slowly cooled to room temperature, the β-cesium cadmium silicon sulfide (β-Cs2CdSi4S10) compound was obtained.

### Example 6. Preparation of β--Cs2CdSi4S10 Compound

According to the chemical reaction formula 2CsI+CdS+4SiS2+S→Cs2CdSi4S10°I2↑, the β-Cs2CdSi4S10 compound is synthesized:

CsI powder, CdS powder, SiS2 powder, and S powder were mixed evenly in a molar ratio of Cs:Cd:Si:S of 2:1:4:10, and were placed in a quartz tube with a diameter of 45 mm. The quartz tube was evacuated to a vacuum degree of 1×10−3 Pa, sealed with a flame and then placed in a muffle furnace. The muffle furnace was heated at a rate of 10° C./h to 630° C. for 24 hours, then slowly cooled to room temperature, the β-cesium cadmium silicon sulfide (β-Cs2CdSi4S10) compound was obtained.

### Example 7. Preparation of a β-Cs2CdSi4S10 Infrared Nonlinear Optical Crystal Adopting a Bridgeman-Stockbarge Method

The β-Cs2CdSi4S10 compound obtained in Example 1 and NaI were mixed in a ratio of 1:2 and placed into a platinum crucible. The platinum crucible was sealed and then placed in a growth furnace. The growth furnace was heated to 640° C. for 100 hours. Then the platinum crucible was lowered at a rate of 10 mm/day while keeping the temperature of the growth furnace constant. It was quickly cooled at a rate of 5° C./h to room temperature after finishing the growth. Finally, the platinum crucible was opened, a β-Cs2CdSi4S10 infrared nonlinear optical crystal with a size of 4 mm×2 mm×2 mm was obtained.

### Example 8. Preparation of a β-Cs2CdSi4S10 Infrared Nonlinear Optical Crystal Adopting a Bridgeman-Stockbarge Method

The β-Cs2CdSi4S10 compound obtained in Example 1 and CsI in a ratio of 1:1 were mixed and placed into a platinum crucible. The platinum crucible was sealed and then placed in a growth furnace. The growth furnace was heated to 645° C. for 110 hours. Then the platinum crucible was lowered at a rate of 3 mm/day while cooled at a rate of 2.5° C./h to 300° C. It was quickly cooled at a rate of 8° C./h to room temperature after finishing the growth. Finally, the platinum crucible was opened, a β-Cs2CdSi4S10 infrared nonlinear optical crystal with a size of 6 mm×3.2 mm×2 mm was obtained.

### Example 9. Preparation of a β-Cs2CdSi4S10 Infrared Nonlinear Optical Crystal Adopting a Bridgeman-Stockbarge Method

The β-Cs2CdSi4S10 compound obtained in Example 1 and BaBr2 in a ratio of 1:1 were mixed and placed into a platinum crucible. The platinum crucible was sealed and then placed in a growth furnace. The growth furnace was heated to 650° C. for 150 hours. Then the platinum crucible was lowered at a rate of 5 mm/day while keeping the temperature of the growth furnace constant. It was quickly cooled at a rate of 10° C./h to room temperature after finishing the growth. Finally, the platinum crucible was opened, a β-Cs2CdSi4S10 infrared nonlinear optical crystal with a size of 5 mm+2.5 mm+1 mm was obtained.

### Example 10. Preparation of a β-Cs2CdSi4S10 Infrared Nonlinear Optical Crystal Adopting a Bridgeman-Stockbarge Method

The β-Cs2CdSi4S10 compound obtained in Example 1 and NaBr in a ratio of 1:2 were mixed and placed into a platinum crucible. The platinum crucible was sealed and then placed in a growth furnace. The growth furnace was heated to 660° C. for 180 hours. Then the platinum crucible was lowered at a rate of 10 mm/day while cooled at a rate of 3° C./h to 300° C. It was quickly cooled at a rate of 12° C./h to room temperature after finishing the growth. Finally, the platinum crucible was opened, a β-Cs2CdSi4S10 infrared nonlinear optical crystal with a size of 5 mm×2.5 mm×2.5 mm was obtained.

### Example 11. Preparation of a β-Cs2CdSi4S10 Infrared Nonlinear Optical Crystal Adopting a Bridgeman-Stockbarge Method

The β-Cs2CdSi4S10 compound obtained in Example 1 and CaCl2 in a ratio of 1:1 were mixed and placed into a platinum crucible. The platinum crucible was sealed and then placed in a growth furnace. The growth furnace was heated to 670° C. for 200 hours. Then the platinum crucible was lowered at a rate of 10 mm/day while keeping the temperature of the growth furnace constant. It was quickly cooled at a rate of 15° C./h to room temperature after finishing the growth. Finally, the platinum crucible was opened, a β-Cs2CdSi4S10 infrared nonlinear optical crystal with a size of 5.5 mm×3 mm×2 mm was obtained.

### Example 12. Preparation of a β-Cs2CdSi4S10 Infrared Nonlinear Optical Crystal Adopting a Bridgeman-Stockbarge Method

The β-Cs2CdSi4S10 compound obtained in Example 1 and LaCl3 in a ratio of 1:1 were mixed and placed into a platinum crucible. The platinum crucible was sealed and then placed in a growth furnace. The growth furnace was heated to 655° C. for 130 hours. Then the platinum crucible was lowered at a rate of 2 mm/day while cooled at a rate of 2° C./h to 300° C. It was quickly cooled at a rate of 11° C./h to room temperature after finishing the growth. Finally, the platinum crucible was opened, a β-Cs2CdSi4S10 infrared nonlinear optical crystal with a size of 6.5 mm×4 mm×2.5 mm was obtained.

### Example 13. Preparation of a β-Cs2CdSi4S10 Infrared Nonlinear Optical Crystal Adopting a Vacuum Packaging Method

The β-Cs2CdSi4S10 compound obtained in Example 2 was placed into a quartz tube. The quartz tube was evacuated to a vacuum degree of 1×10−3 Pa. After sealing the quartz tube at high temperature, it was placed in a muffle furnace and heated to 640° C. for 100 hours. Then, it was cooled at a rate of 3° C./h to 300° C. and rapidly cooled a rate of 6° C./h to room temperature. Finally, the quartz tube was opened, a β-Cs2CdSi4S10 infrared nonlinear optical crystal with a size of 1 mm×1 mm×1 mm was obtained.

### Example 14. Preparation of a β-Cs2CdSi4S10 Infrared Nonlinear Optical Crystal Adopting a Vacuum Packaging Method

The β-Cs2CdSi4S10 compound obtained in Example 3 was placed into a quartz tube. The quartz tube was evacuated to a vacuum degree of 1×10−3 Pa. After sealing the quartz tube at high temperature, it was placed in a muffle furnace and heated to 650° C. for 100 hours. Then, it was cooled at a rate of 3° C./h to 300° C. and rapidly cooled a rate of 7° C./h to room temperature. Finally, the quartz tube was opened, a β-Cs2CdSi4S10 infrared nonlinear optical crystal with a size of 0.8 mm×0.8 mm×0.5 mm was obtained.

### Example 15. Preparation of a β-Cs2CdSi4S10 Infrared Nonlinear Optical Crystal Adopting a Vacuum Packaging Method

The β-Cs2CdSi4S10 compound obtained in Example 4 was placed into a quartz tube. The quartz tube was evacuated to a vacuum degree of 1×10−3 Pa. After sealing the quartz tube at high temperature, it was placed in a muffle furnace and heated to 650° C. for 100 hours. Then, it was cooled at a rate of 3° C./h to 300° C. and rapidly cooled a rate of 8° C./h to room temperature. Finally, the quartz tube was opened, a β-Cs2CdSi4S10 infrared nonlinear optical crystal with a size of 1 mm×0.5 mm×0.5 mm was obtained.

### Example 16. Preparation of a β-Cs2CdSi4S10 Infrared Nonlinear Optical Crystal Adopting a Vacuum Packaging Method

The β-Cs2CdSi4S10 compound obtained in Example 5 was placed into a quartz tube. The quartz tube was evacuated to a vacuum degree of 1×10−3 Pa. After sealing the quartz tube at high temperature, it was placed in a muffle furnace and heated to 650° C. for 100 hours. Then, it was cooled at a rate of 3° C./h to 300° C. and rapidly cooled a rate of 9° C./h to room temperature. Finally, the quartz tube was opened, a β-Cs2CdSi4S10 infrared nonlinear optical crystal with a size of 0.8 mm×0.5 mm×0.5 mm was obtained.

### Example 17. Preparation of a β-Cs2CdSi4S10 Infrared Nonlinear Optical Crystal Adopting a Vacuum Packaging Method

The β-Cs2CdSi4S10 compound obtained in Example 6 was placed into a quartz tube. The quartz tube was evacuated to a vacuum degree of 1×10−3 Pa. After sealing the quartz tube at high temperature, it was placed in a muffle furnace and heated to 650° C. for 100 hours. Then, it was cooled at a rate of 3° C./h to 300° C. and rapidly cooled a rate of 10° C./h to room temperature. Finally, the quartz tube was opened, a β-Cs2CdSi4S10 infrared nonlinear optical crystal with a size of 1.1 mm×0.8 mm×0.5 mm was obtained.

### Example 18. Performance of Compounds and Nonlinear Optical Crystals

The Performances of the β-Cs2CdSi4S10 compounds prepared in Examples 1-6 and the β-Cs2CdSi4S10 infrared nonlinear optical crystals prepared in Examples 7 -17 are tested.

After testing, the β-Cs2CdSi4S10 infrared nonlinear optical crystal of the present invention belongs to the tetragonal crystal system, its space group is I-4, and its unit cell parameters are: a=8.4233(7) Å, c=14.6136(12) Å, and the unit cell volume is 1036.86(19) Å3.

FIG. 1 shows the powder XRD spectrum of the β-Cs2CdSi4S10 compound prepared in Example 1 of the present invention.

FIG. 2 shows the UV-visible diffuse reflection of the β-Cs2CdSi4S10 infrared nonlinear optical crystal prepared in Example 7 of the present invention. The crystal bandgap is 4.21 eV, the UV cutoff edge is 254 nm, and the infrared transparency range is greater than 13 μm.

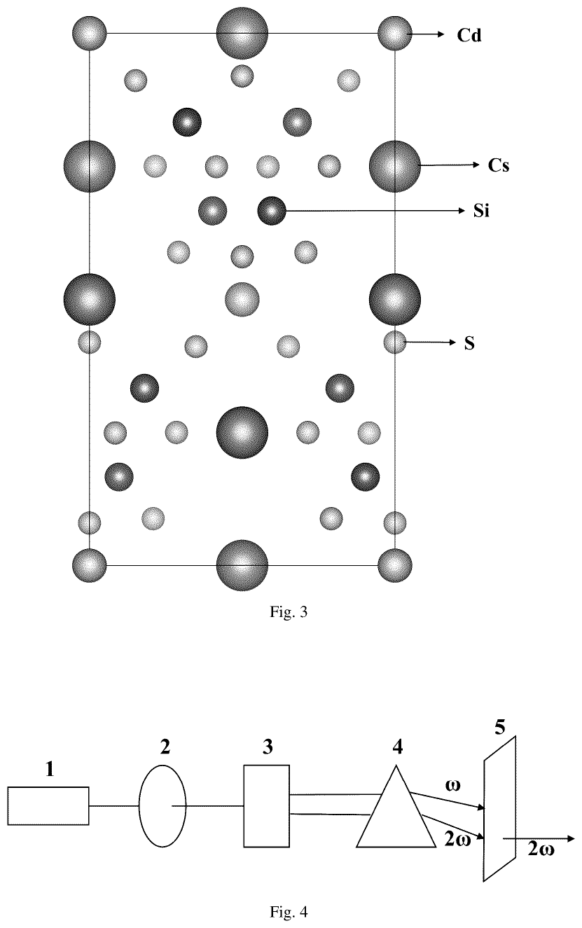

FIG. 3 is a schematic diagram of the structure of the β-Cs2CdSi4S10 infrared nonlinear optical crystal of the present invention. In the crystal, the valences of Cs atom, Cd atom, Si atom, and S atom are +1, +2, +4, and −2, respectively. Si atom and Cd atom form tetrahedral structures of [SiS4] and [CdS4] with four adjacent S atoms, respectively. The four adjacent tetrahedra of [SiS4] form a super tetrahedron of [Si4S10] with a common vertex, which is connected to the tetrahedron of [CdS4] with a common vertex. All tetrahedra are arranged in a consistent orientation, forming a defect like diamond-like structure framework.

By using the kurtz-berry method, it was found that the frequency doubling effect of β-Cs2CdSi4S10 crystal is approximately 1.2 times that of AgGaS2(AGS).

It can be seen that the β-Cs2CdSi4S10 infrared nonlinear optical crystal of the present invention has a wide bandgap, a large nonlinear coefficient, a wide transmission range, and a moderate birefringence.

### Example 19. Application in Nonlinear Optical Devices

Any of the β-Cs2CdSi4S10 infrared nonlinear optical crystals obtained in Examples 7 -17 was placed at position 3, as shown in FIG. 4. At room temperature, when using a output with a wavelength of 2090 nm emitted by Q-switched Ho:Tm:Cr:YAG laser as the light source, it was observed a significant frequency doubled light with a wavelength of 1045 nm was output and its output intensity is about 1.2 times that of AgGaS2 under the same conditions. The infrared beam with a wavelength of 2090 nm emitted by Q-switched Ho:Tm:Cr:YAG laser 1 is incident on the β-Cs2CdSi4S10 infrared nonlinear optical crystal through a full focusing lens 2, generating a frequency doubled light with a wavelength of 1045 nm; the output beam 4 contains infrared light with a wavelength of 2090 nm and 1045 nm; by filtered with filter 5, a frequency doubled light with a wavelength of 1045 nm was obtained.

In summary, the preparation method of the β-Cs2CdSi4S10 infrared nonlinear optical crystal of the present invention is simple, with a short growth period, and avoids the leakage and contamination of raw materials.

The β-Cs2CdSi4S10 infrared nonlinear optical crystal of the present invention can be used to fabricate conversion devices for high-power laser output applications and has important applications in atmospheric remote sensing and communication fields.

1. A β-cesium cadmium silicon sulfide compound, with a chemical formula β-Cs2CdSi4S10 and a molecular weight of 755.04.

2. A method for preparing a β-Cs2CdSi4S10 compound using vacuum packaging method.

3. The method for preparing a β-Cs2CdSi4S10 compound according to claim 2, comprising the following steps:
Mixing evenly a Cs-containing compound, a Cd-containing compound, a Si-containing compound, and a S-containing compound in a molar ratio of Cs:Cd:Si:S of 2:1:4:10 and placing them in a quartz tube; evacuating the quartz tube to a vacuum degree of 1×10−3 Pa; sealing the quartz tube with a flame and placing it in a muffle furnace; heating the muffle furnace at a rate of 5-10° C./h to 630° C. and maintaining the temperature for 24 hours, then slowly cooling it to room temperature to obtain the desired β-Cs2CdSi4S10 compound,
wherein, the Cs-containing compound is CsI, the Cd-containing compound is CdS or Cd simple substance; the Si-containing compound is SiS2 or Si simple substance, and the S-containing compound is S simple substance.

4. A β-Cs2CdSi4S10 infrared nonlinear optical crystal, characterized in that the crystal belongs to the tetragonal crystal system, its space group is I-4, and its unit cell parameters are: a=8.4233(7) Å, c=14.6136(12) Å, and the unit cell volume is 1036.86(19) Å3.

5. A method for preparing a β-Cs2CdSi4S10 infrared nonlinear optical crystal, which adopts a Bridgeman-Stockbarge method, comprising the following steps:
a. Placing the β-Cs2CdSi4S10 compound prepared by a vacuum packaging method in a muffle furnace, heating the muffle furnace to 650° C. and maintaining the temperature for 100 hours to obtain a mixed melt;
b. Obtaining seed crystals of β-Cs2CdSi4S10 by slowly cooling the mixed melt obtained in step a at a rate of 3° C./h to 300° C. and then rapidly cooling it at a rate of 5-15° C./h to room temperature;
c. Placing the seed crystal prepared in step b at the bottom of a platinum crucible, and then placing the β-Cs2CdSi4S10 compound prepared in step a into the platinum crucible; sealing the platinum crucible and then placing it in a growth furnace; heating the growth furnace to 640-670° C. and maintaining the temperature for 100-200 hours; then lowering the platinum crucible at a rate of 1-10 mm/day while keeping the temperature of the growth furnace constant or cooling it at a rate of 2-3° C./h to 300° C.; quickly cooling it at a rate of 5-15° C./h to room temperature after finishing the growth; finally, opening the platinum crucible to obtain the desired β-Cs2CdSi4S10 infrared nonlinear optical crystal.

6. The method for preparing a β-Cs2CdSi4S10 infrared nonlinear optical crystal according to claim 5, wherein the growth furnace is a Bridgeman-Stockbarge furnace.

7. A method for preparing a β-Cs2CdSi4S10 infrared nonlinear optical crystal, which adopts a vacuum packaging method, comprising the following steps:
Placing the β-Cs2CdSi4S10 compound prepared by a vacuum packaging method in a quartz tube; evacuating the quartz tube to a vacuum degree of 1×10⁻3 Pa; sealing the quartz tube at high temperature and placing it in a muffle furnace; heating the muffle furnace to 630-650° C. and maintaining the temperature for 100 hours, then cooling it at a rate of 3° C./h to 300° C. and then rapidly cooling it at a rate of 5-10° C./h to room temperature; finally, opening the quartz tube to obtain the desired β-Cs2CdSi4S10 infrared nonlinear optical crystal.

8. The use of the β-Cs2CdSi4S10 infrared nonlinear optical crystal according to claim 4 in laser frequency conversion crystal devices for mid-infrared to far-infrared bands.
